(19) United States
(12) Patent Application Publication
(10) Pub. No.: US 2017/0343620 A1
(43) Pub. Date: Nov. 30, 2017

(54) MAGNETO-OPTICAL DEFECT CENTER DEVICE INCLUDING LIGHT PIPE WITH OPTICAL COATINGS

(71) Applicant: Lockheed Martin Corporation, Bethesda, MD (US)

(72) Inventors: Joseph W. Hahn, Erial, NJ (US); Wilbur Lew, Mount Laurel, NJ (US); Nick Luzod, Bethesda, MD (US); Gregory Scott Bruce, Abington, PA (US)

(73) Assignee: Lockheed Martin Corporation, Bethesda, MD (US)

(21) Appl. No.: 15/440,194

(22) Filed: Feb. 23, 2017

Related U.S. Application Data
(60) Provisional application No. 62/343,758, filed on May 31, 2016.
(60) Provisional application No. 62/343,746, filed on May 31, 2016.
(60) Provisional application No. 62/343,750, filed on May 31, 2016.

(51) Int. Cl. G01R 33/032

(52) U.S. Cl. CPC G01R 33/032

(57) ABSTRACT

Systems and methods using a magneto-optical defect center material magnetic sensor system that uses fluorescence intensity to distinguish the mₛ=±1 states, and to measure the magnetic field based on the energy difference between the mₛ=+1 state and the mₛ=−1 state, as manifested by the RF frequencies corresponding to each state in some embodiments. The system may include an optical excitation source, which directs optical excitation to the material. The system may further include an RF excitation source, which provides RF radiation to the material. Light from the material may be directed through a light pipe to an optical detector. Light from the material may be directed through an optical filter to an optical detector.

### CROSS-REFERENCE TO RELATED PATENT APPLICATIONS

This application claims priority to U.S. Provisional Patent Application No. 62/343,750, filed May 31, 2016, entitled “DNV DEVICE INCLUDING LIGHT PIPE,” attorney docket no. 111423-1139, the entire contents of which are incorporated by reference herein in their entirety and for all purposes.

This application claims priority to U.S. Provisional Patent Application No. 62/343,746, filed May 31, 2016, entitled “DNV DEVICE INCLUDING LIGHT PIPE WITH OPTICAL COATINGS,” attorney docket no. 111423-1138, the entire contents of which are incorporated by reference herein in their entirety and for all purposes.

This application claims priority to U.S. Provisional Patent Application No. 62/343,758, filed May 31, 2016, entitled “OPTICAL FILTRATION SYSTEM FOR DIAMOND MATERIAL WITH NITROGEN VACANCY CENTERS,” attorney docket no. 111423-1140, the entire contents of which are incorporated by reference herein in their entirety and for all purposes.

### FIELD

The present disclosure generally relates to magnetic sensor systems, and more particularly, to magnetic sensor systems including a nitrogen vacancy diamond material.

### BACKGROUND

Many advanced magnetic imaging systems can operate in limited conditions, for example, high vacuum and/or cryogenic temperatures, which can make them inapplicable for imaging applications that require ambient conditions. Small size, weight and power (SWAP) magnetic sensors of moderate sensitivity, vector accuracy, and bandwidth are valuable in many applications.

### SUMMARY

According to certain embodiments, a system for magnetic detection may include: a nitrogen vacancy (NV) diamond material comprising a plurality of NV centers; a radio frequency (RF) excitation source configured to provide RF excitation to the NV diamond material; an optical detector configured to receive an optical signal emitted by the NV diamond material; an optical light source; and an optical waveguide assembly. The optical waveguide assembly may include a light pipe and at least one optical filter coating. The optical waveguide assembly may include a light pipe. The optical waveguide assembly may include an optical waveguide and at least one optical filter coating. The optical waveguide assembly is configured to transmit light emitted from the NV diamond material to the optical detector. In general, the system for magnetic detection may instead employ a different magneto-optical defect center material, with a plurality of magneto-optical defect centers. Magneto-optical defect center materials include but are not limited to diamonds, Silicon Carbide (SiC) and other materials with nitrogen, boron, or other defect centers.

According to certain embodiments, the optical waveguide assembly includes at least one optical filter coating. The optical filter coating may transmit greater than about 99% of light with a wavelength of about 650 nm to about 850 nm. The optical filter coating may transmit less than 0.1% of light with a wavelength of less than about 600 nm. The optical filter coating may transmit greater than about 99% of light with a wavelength of about 650 nm to about 850 nm and less than 0.1% of light with a wavelength of less than about 600 nm. The optical filter coating may be disposed on an end surface of the optical waveguide adjacent the optical detector. A first optical filter coating may be disposed on an end surface of the optical waveguide adjacent the optical detector, and a second optical filter coating may be disposed on an end surface of the optical waveguide adjacent the NV diamond material. According to certain embodiments, the optical waveguide includes a light pipe.

According to certain embodiments, the light pipe has an aperture with a size that is smaller than a size of the optical detector.

According to certain embodiments, the light pipe has an aperture with a size greater than a size of a surface of the NV diamond material adjacent to the light pipe.

According to certain embodiments, the light pipe has an aperture with a size that is smaller than a size of the optical detector and greater than a size of a surface of the NV diamond material adjacent the light pipe.

According to certain embodiments, the optical waveguide assembly further comprises an optical coupling material disposed between the light pipe and the NV diamond material, and the optical coupling material is configured to optically couple the light pipe to the NV diamond material.

According to certain embodiments, the optical waveguide assembly further comprises an optical coupling material disposed between the light pipe and the optical detector, and the optical coupling material is configured to optically couple the light pipe to the optical detector.

According to certain embodiments, an end surface of the light pipe adjacent to the NV diamond material extends in a plane parallel to a surface of the NV diamond material adjacent to the light pipe.

According to certain embodiments, the system for magnetic detection further includes a second optical waveguide assembly and a second optical detector, wherein the optical waveguide assembly is configured to transmit light emitted from the NV diamond material to the optical detector.

According to certain embodiments, a method of magnetic detection using a nitrogen vacancy (NV) diamond material comprising a plurality of NV centers may comprise: providing radio frequency (RF) excitation to the NV diamond material by an RF excitation source, transmitting light emitted from the NV diamond material to an optical detector using a waveguide assembly comprising a light pipe, and receiving an optical signal comprising the light emitted by the NV diamond material by the optical detector.

According to certain embodiments, a system for magnetic detection may include: a nitrogen vacancy (NV) diamond material comprising a plurality of NV centers; a means for providing RF excitation to the NV diamond material; a means for receiving an optical signal emitted by the NV diamond material by an optical detector; an optical light source; and a means for transmitting light emitted from the NV diamond material to the optical detector.

### BRIEF DESCRIPTION OF THE DRAWINGS

FIG. 1 illustrates one orientation of an NV center in a diamond lattice.

FIG. 2 illustrates an energy level diagram showing energy levels of spin states for the NV center in some embodiments.

FIG. 3 illustrates a schematic diagram of a NV center magnetic sensor system in some embodiments.

FIG. 4 is a graph illustrating the fluorescence as a function of an applied RF frequency of an NV center along a given direction for a zero magnetic field, and also for a non-zero magnetic field having a component along the NV axis in some embodiments.

FIG. 5 is a graph illustrating the fluorescence as a function of an applied RF frequency for four different NV center orientations for a non-zero magnetic field in some embodiments.

FIG. 6 is a schematic diagram illustrating a magnetic field sensor system according to some embodiments.

FIG. 7 is a side-view illustrating details of the optical waveguide assembly of the magnetic field sensor system of FIG. 6 according to some embodiments.

FIG. 8 is a depiction of a cross-section of a light pipe and an associated mount according to some embodiments.

FIG. 9 is a top-down view of an optical waveguide assembly of a magnetic field sensor system according to some embodiments.

FIG. 10 is a schematic diagram illustrating a dichroic optical filter and the behavior of light interacting therewith according to some embodiments.

### DETAILED DESCRIPTION

Atomic-sized nitrogen-vacancy (NV) centers in diamond have excellent sensitivity for magnetic field measurement and enable fabrication of small magnetic sensors that can readily replace existing-technology (e.g., Hall-effect) systems and devices. The sensing capabilities of diamond NV (DNV) sensors are maintained at room temperature and atmospheric pressure, and these sensors can be even used in liquid environments (e.g., for biological imaging). DNV sensing allows measurement of 3-D vector magnetic fields that is beneficial across a very broad range of applications, including communications, geological sensing, navigation, and attitude determination. In general, the magnetic sensors may instead employ a different magneto-optical defect center material, with a plurality of magneto-optical defect centers. Magneto-optical defect center materials include but are not limited to diamonds, Silicon Carbide (SiC) and other materials with nitrogen, boron, or other defect centers.

### The NV Center, its Electronic Structure, and Optical and RF Interaction

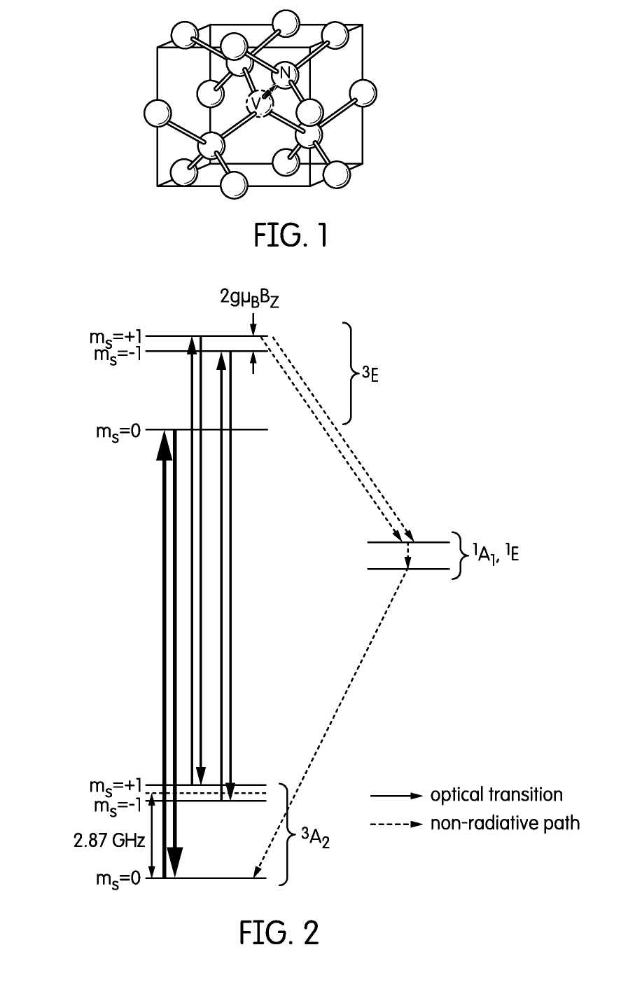

The NV center in a diamond comprises a substitutional nitrogen atom in a lattice site adjacent a carbon vacancy as shown in FIG. 1. The NV center may have four orientations, each corresponding to a different crystallographic orientation of the diamond lattice.

The NV center may exist in a neutral charge state or a negative charge state. The neutral charge state uses the nomenclature NV⁰, while the negative charge state uses the nomenclature NV, which is adopted in this description.

The NV center has a number of electrons, including three unpaired electrons, each one from the vacancy to a respective of the three carbon atoms adjacent to the vacancy, and a pair of electrons between the nitrogen and the vacancy. The NV center, which is in the negatively charged state, also includes an extra electron.

The NV center has rotational symmetry, and as shown in FIG. 2, has a ground state, which is a spin triplet with ³A₂ symmetry with one spin state mₛ=0, and two further spin states mₛ=+1, and mₛ=−1. In the absence of an external magnetic field, the mₛ=±1 energy levels are offset from the mₛ=0 due to spin-spin interactions, and the mₛ=±1 energy levels are degenerate, i.e., they have the same energy. The mₛ=0 spin state energy level is split from the mₛ=±1 energy levels by an energy of approximately 2.87 GHz for a zero external magnetic field.

Introducing an external magnetic field with a component along the NV axis lifts the degeneracy of the mₛ=±1 energy levels, splitting the energy levels mₛ=±1 by an amount 2 gμ_{B}Bz, where g is the g-factor, μ_{B} is the Bohr magneton, and Bz is the component of the external magnetic field along the NV axis. This relationship is correct to a first order and inclusion of higher order corrections is a straightforward matter and will not affect the computational and logic steps in the systems and methods described below.

The NV center electronic structure further includes an excited triplet state ³E with corresponding mₛ=0 and mₛ=±1 spin states. The optical transitions between the ground state ³A₂ and the excited triplet ³E are predominantly spin conserving, meaning that the optical transitions are between initial and final states that have the same spin. For a direct transition between the excited triplet ³E and the ground state ³A₂, a photon of red light can be emitted with a photon energy corresponding to the energy difference between the energy levels of the transitions.

There is, however, an alternative non-radiative decay route from the triplet ³E to the ground state ³A₂ via intermediate electron states, which are thought to be intermediate singlet states A, E with intermediate energy levels. Significantly, the transition rate from the mₛ=±1 spin states of the excited triplet ³E to the intermediate energy levels can be significantly greater than the transition rate from the mₛ=0 spin state of the excited triplet ³E to the intermediate energy levels. The transition from the singlet states A, E to the ground state triplet ³A₂ predominantly decays to the mₛ=0 spin state over the mₛ=±1 spins states. These features of the decay from the excited triplet ³E state via the intermediate singlet states A, E to the ground state triplet ³A₂ allows that if optical excitation is provided to the system, the optical excitation will eventually pump the NV center into the mₛ=0 spin state of the ground state ³A₂. In this way, the population of the mₛ=0 spin state of the ground state ³A₂ may be “reset” to a maximum polarization determined by the decay rates from the triplet ³E to the intermediate singlet states.

Another feature of the decay can be that the fluorescence intensity due to optically stimulating the excited triplet ³E state can be less for the mₛ=±1 states than for the mₛ=0 spin state. This can be so because the decay via the intermediate states does not result in a photon emitted in the fluorescence band, and because of the greater probability that the mₛ=±1 states of the excited triplet ³E state will decay via the non-radiative decay path. The lower fluorescence intensity for the mₛ=±1 states than for the mₛ=0 spin state allows the fluorescence intensity to be used to determine the spin state. As the population of the mₛ=±1 states increases relative to the mₛ=0 spin, the overall fluorescence intensity will be reduced.

The NV Center, or Magneto-Optical Defect Center, Magnetic Sensor System

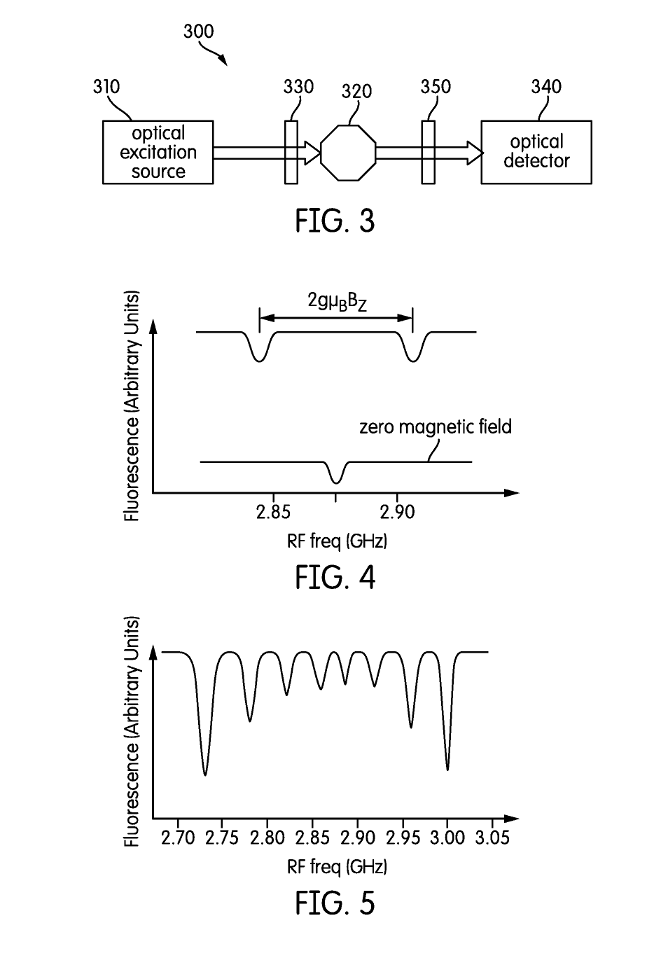

FIG. 3 is a schematic diagram illustrating a NV center magnetic sensor system 300 that uses fluorescence intensity to distinguish the mₛ=±1 states, and to measure the magnetic field based on the energy difference between the mₛ=+1 state and the mₛ=−1 state, as manifested by the RF frequencies corresponding to each state in some embodiments. The system 300 includes an optical excitation source 310, which directs optical excitation to an NV diamond material 320 with NV centers. The system further includes an RF excitation source 330, which provides RF radiation to the NV diamond material 320. Light from the NV diamond may be directed through an optical filter 350 to an optical detector 340.

The RF excitation source 330 may be a microwave coil, for example. The RF excitation source 330, when emitting RF radiation with a photon energy resonant with the transition energy between ground mₛ=0 spin state and the mₛ=+1 spin state, excites a transition between those spin states. For such a resonance, the spin state cycles between ground mₛ=0 spin state and the mₛ=+1 spin state, reducing the population in the mₛ=0 spin state and reducing the overall fluorescence at resonances. Similarly, resonance and a subsequent decrease in fluorescence intensity occurs between the mₛ=0 spin state and the mₛ=−1 spin state of the ground state when the photon energy of the RF radiation emitted by the RF excitation source is the difference in energies of the mₛ=0 spin state and the mₛ=−1 spin state.

The optical excitation source 310 may be a laser or a light emitting diode, for example, which emits light in the green (light having a wavelength such that the color is green), for example. The optical excitation source 310 induces fluorescence in the red, which corresponds to an electronic transition from the excited state to the ground state. Light from the NV diamond material 320 can be directed through the optical filter 350 to filter out light in the excitation band (in the green, for example), and to pass light in the red fluorescence band, which in turn can be detected by the detector 340. The optical excitation light source 310, in addition to exciting fluorescence in the diamond material 320, also serves to reset the population of the mₛ=0 spin state of the ground state ³A₂ to a maximum polarization, or other desired polarization.

For continuous wave excitation, the optical excitation source 310 continuously pumps the NV centers, and the RF excitation source 330 sweeps across a frequency range that includes the zero splitting (when the mₛ=±1 spin states have the same energy) photon energy of approximately 2.87 GHz. The fluorescence for an RF sweep corresponding to a diamond material 320 with NV centers aligned along a single direction is shown in FIG. 4 for different magnetic field components Bz along the NV axis, where the energy splitting between the mₛ=−1 spin state and the mₛ=+1 spin state increases with Bz. Thus, the component Bz may be determined. Optical excitation schemes other than continuous wave excitation are contemplated, such as excitation schemes involving pulsed optical excitation, and pulsed RF excitation. Examples of pulsed excitation schemes include Ramsey pulse sequence (described in more detail below), and spin echo pulse sequence.

In general, the diamond material 320 will have NV centers aligned along directions of four different orientation classes. FIG. 5 illustrates fluorescence as a function of RF frequency for the case where the diamond material 320 has NV centers aligned along directions of four different orientation classes. In this case, the component Bz along each of the different orientations may be determined. These results, along with the known orientation of crystallographic planes of a diamond lattice, allow not only the magnitude of the external magnetic field to be determined, but also the direction of the magnetic field.

While FIG. 3 illustrates an NV center magnetic sensor system 300 with NV diamond material 320 with a plurality of NV centers, in general, the magnetic sensor system may instead employ a different magneto-optical defect center material, with a plurality of magneto-optical defect centers. Magneto-optical defect center materials include but are not limited to diamonds, Silicon Carbide (SiC) and other materials with nitrogen, boron, or other defect centers. The electronic spin state energies of the magneto-optical defect centers shift with magnetic field, and the optical response, such as fluorescence, for the different spin states is not the same for all of the different spin states. In this way, the magnetic field may be determined based on optical excitation, and possibly RF excitation, in a corresponding way to that described above with NV diamond material.

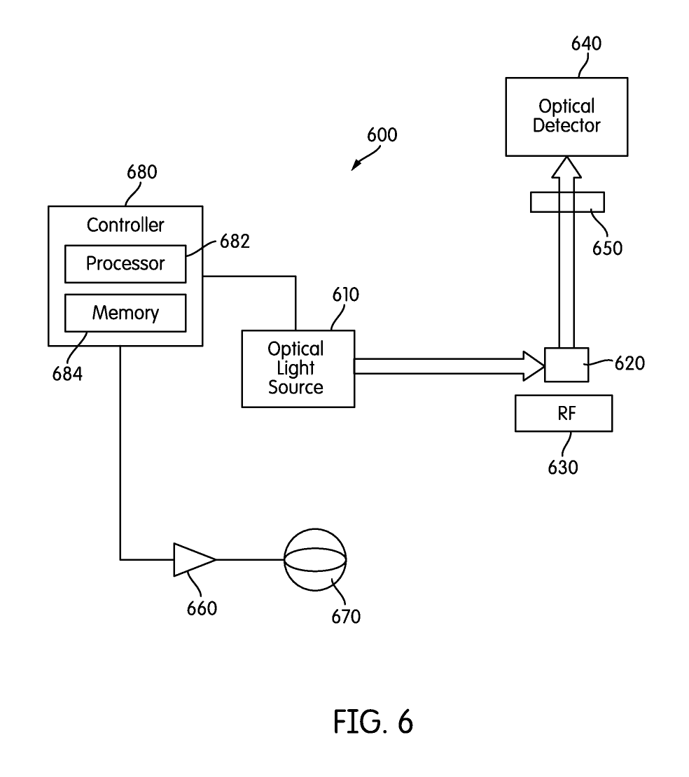

FIG. 6 is a schematic diagram of a system 600 for a magnetic field sensor system according to some embodiments.

The system 600 includes an optical light source 610, which directs optical light to an NV diamond material 620 with NV centers, or another magneto-optical defect center material with magneto-optical defect centers. An RF excitation source 630 provides RF radiation to the NV diamond material 620. The system 600 may include a magnetic field generator 670 which generates a magnetic field, which may be detected at the NV diamond material 620, or the magnetic field generator 670 may be external to the system 600. The magnetic field generator 670 may provide a biasing magnetic field.

The system 600 further includes a controller 680 arranged to receive a light detection signal from the optical detector 640 and to control the optical light source 610, the RF excitation source 630, and the magnetic field generator 670. The controller may be a single controller, or multiple controllers. For a controller including multiple controllers, each of the controllers may perform different functions, such as controlling different components of the system 600. The magnetic field generator 670 may be controlled by the controller 680 via an amplifier 660, for example.

The RF excitation source 630 may include a microwave coil or coils, for example. The RF excitation source 630 may be controlled to emit RF radiation with a photon energy resonant with the transition energy between the ground mₛ=0 spin state and the mₛ=±1 spin states as discussed above with respect to FIG. 3, or to emit RF radiation at other nonresonant photon energies.

The controller 680 can be arranged to receive a light detection signal from the optical detector 640 and to control the optical light source 610, the RF excitation source 630, and the magnetic field generator 670. The controller 680 may include a processor 682 and a memory 684, in order to control the operation of the optical light source 610, the RF excitation source 630, and the magnetic field generator 670. The memory 684, which may include a nontransitory computer readable medium, may store instructions to allow the operation of the optical light source 610, the RF excitation source 630, and the magnetic field generator 670 to be controlled. That is, the controller 680 may be programmed to provide control.

Optical Waveguide

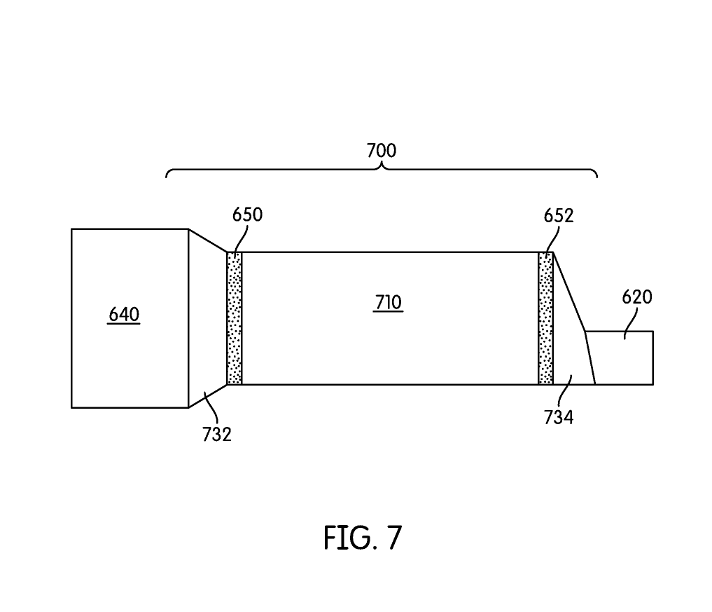

FIG. 7 is a schematic illustrating details of an optical waveguide assembly 700 that transmits light from the NV diamond material 620 to the optical detector 640 in some embodiments. The optical waveguide assembly 700 may include an optical waveguide 710 and an optical filter 650 to filter out light in the excitation band (in the green, for example), and to pass light in the red fluorescence band, which in turn is detected by the optical detector 640.

The optical waveguide 710 may be any appropriate optical waveguide. In some embodiments, the optical waveguide is a light pipe. The light pipe may have any appropriate geometry. In some embodiments, the light pipe may have a circular cross-section, square cross-section, rectangular cross-section, hexagonal cross-section, or octagonal cross-section. A hexagonal cross-section may be preferred, as a light pipe with a hexagonal cross-section exhibits less light loss than a light pipe with a square cross-section and is capable of being mounted with less contact area than a light pipe with a circular cross-section.

The light pipe 710 may be formed from any appropriate material. In some embodiments, the light pipe may be formed from a borosilicate glass material. The light pipe may be formed of a material capable of transmitting light in the wavelength range of about 350 nm to about 2,200 nm. In some embodiments, the light pipe may be a commercially available light pipe.

The optical filter 650 may be any appropriate optical filter capable of transmitting red light and reflecting other light, such as green light. In some embodiments, the optical filter 650 may be a coating applied to an end surface of the light pipe 710. The coating may be any appropriate anti-reflection coating for red light. In some embodiments, the anti-reflective coating may exhibit greater than 99% transmittance for light in the wavelength range of about 650 nm to about 850 nm. Preferably, the anti-reflective coating may exhibit greater than 99.9% transmittance for light in the wavelength range of about 650 nm to about 850 nm. The optical filter 650 may be disposed on an end surface of the light pipe 710 adjacent to the optical detector 640.

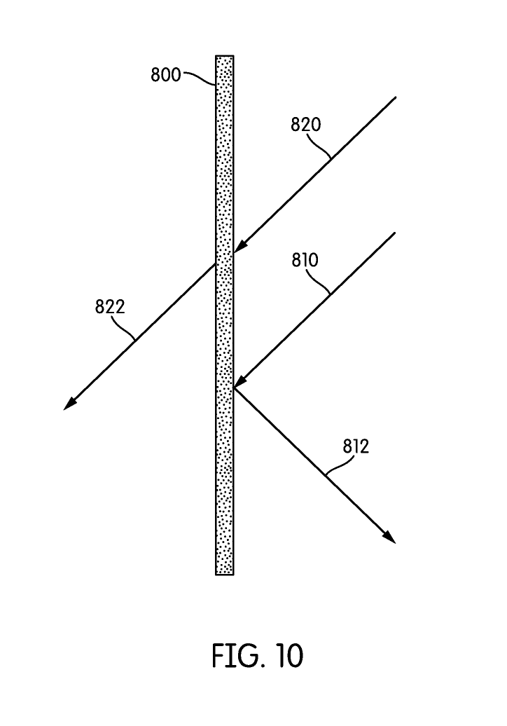

In some embodiments, the optical filter 650 may also be highly reflective for light other than red light, such as green light. Such an optical filter may be a dichroic coating or multiple coatings with the desired cumulative optical properties. The optical filter may exhibit less than about 0.1% transmittance for light with a wavelength of less than about 600 nm. Preferably, the optical filter may exhibit less than about 0.01% transmittance for light with a wavelength of less than about 600 nm. FIG. 10 is a schematic illustrating the behavior of an optical filter 800 with respect to green light 810 and red light 820 according to some embodiments. The optical filter 800 can be anti-reflective for the red light 820, resulting in at least some of the red light 812 transmitted through the optical filter 800. The optical filter 800 can be highly reflective for the green light 810, resulting in green light 822 being reflected by the optical filter 800 and at least most of the green light 822 not transmitted therethrough.

The optical filter 650 may be a coating formed by any appropriate method. In some embodiments, the optical filter 650 may be formed by an ion beam sputtering (IBS) process. The coating may be a single-layer coating or a multi-layer coating. The coating may include any appropriate material, such as magnesium fluoride, silica, hafnia, or tantalum pentoxide. The material for the coating may be selected based on the light pipe material and the material which the coating will be in contact with, such as an optical coupling material, to produce the desired optical properties. The coating may have a hardness that approximately matches the hardness of the light pipe. The coating may have a high density, and exhibit good stability with respect to humidity and temperature.

The optical waveguide assembly 700 may optionally include a second optical filter 652. The second optical filter 652 may be a coating disposed on an end surface of the light pipe 710 adjacent to the diamond material 620. The second optical filter 652 may be any of the coatings described above with respect to the optical filter 650. The inclusion of a second optical filter 652 may improve the performance of the optical waveguide assembly by about 10%, in comparison to an optical waveguide assembly with a single optical filter.

As shown in FIG. 7, the optical waveguide assembly 700 may include an optical coupling material 734 disposed between the light pipe 710 or second optical filter 652 and the diamond material 620. An optical coupling material 732 may also be disposed between the light pipe 710 or optical filter 650 and the optical detector 640. The optical coupling material may be any appropriate optical coupling material, such as a gel or epoxy. In some embodiments, the optical coupling material may be selected to have optical properties, such as an index of refraction, that improves the light transmission between the coupled components. The coupling material may be in the form of a layer formed between the components to be coupled. In some embodiments, the coupling material layer may have a thickness of about 1 microns to about 5 microns. The coupling material may serve to eliminate air gaps between the components to be coupled, increasing the light transmission efficiency. As shown in FIG. 7, the coupling materials 732 and 734 may also account for size mismatches between the components to be coupled. The coupling material may be selected such that an efficiency of the optical waveguide assembly is increased by about 10%. The coupling material may produce a light transmission between the components to be coupled that is functionally equivalent to direct contact between the components to be coupled. In some embodiments, an epoxy coupling material may also serve to mount the diamond material to the optical waveguide assembly, such that other supports for the diamond material are not required. In some embodiments, a coupling material may not be necessary where direct contact between the optical filter or light pipe and the optical detector is achieved. Similarly, a coupling material may not be necessary where direct contact between the light pipe or second optical filter and the diamond material is achieved.

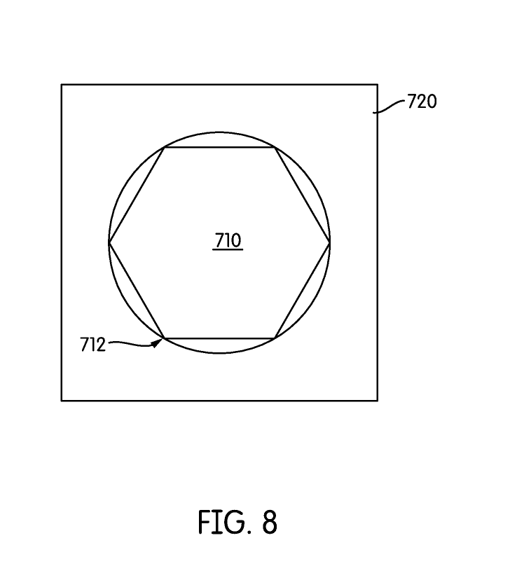

FIG. 8 shows a light pipe 710 with a hexagonal cross-section and the interaction with a mount 720 securing the light pipe 710 within the device in some embodiments. The light pipe 710 may be mounted such that only the vertices 712 of the light pipe 710 contact the mount 720. Such an arrangement allows the light pipe to be securely and rigidly supported by the mount 720, while also reducing the contact area between the mount 720 and the surface of the light pipe 710. Contact between the light pipe and the mount may result in a reduction in the efficiency of the optical waveguide assembly 700. As shown in FIG. 8, a mount 720 with a circular support opening may be successfully employed to support a light pipe 710 with a hexagonal cross-section.

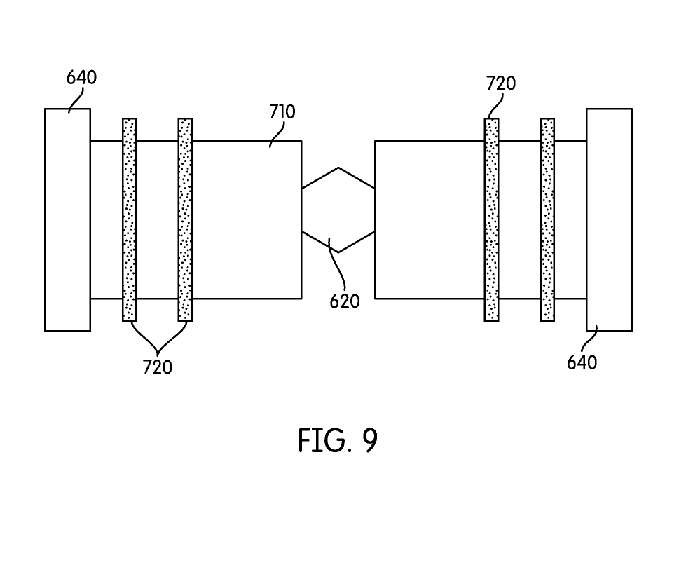

FIG. 9 shows a top down schematic of an arrangement of optical waveguide assemblies according to some embodiments. The optical filters and optical coupling materials are not shown in FIG. 9 for the sake of clarity. As shown in FIG. 9, more than one optical waveguide assembly may be included in the magnetic sensor system, such as two or more optical waveguide assemblies. The inclusion of more than one optical waveguide assemblies allows more than one optical detector 640 to be included in the magnetic sensor device, increasing the amount of light collected and measured by the optical detectors 640. The inclusion of additional optical detectors 640 also increases the amount of noise in the system, which may negatively impact the sensitivity or accuracy of the system. The use of two optical waveguide assemblies may provide a compromise between increased light collection and increased noise. Each optical waveguide assembly in the magnetic sensor system may be associated with a different optical detector, but the same diamond material.

The light pipe 710 may be mounted to the magnetic sensor system by at least one mount 720. In some embodiments, two mounts 720 may support each light pipe 710 in the magnetic sensor system. The light pipe may be mounted to the device rigidly, such that the alignment of the light pipe 710, the optical detector 640, and the diamond material 620 is maintained during operation of the system. The mounting of the light pipe to the magnetic sensor system may be sufficiently rigid to prevent a mechanical response of the light pipe in the region that would affect the measurement of light by the optical detector.

The light pipe can be selected to have an appropriate aperture size. The aperture of the light pipe can be selected to be matched to or smaller than the optical detector. This size relationship allows the optical detector to capture the highest possible percentage of the light emitted by the light pipe. The aperture of the light pipe can be also selected to be larger than the surface of the diamond material to which it is coupled. This size relationship allows the light pipe to capture the highest possible percentage of light emitted by the diamond material. In some embodiments, the light pipe may have an aperture of about 4 mm. In some other embodiments, the light pipe may have an aperture of about 2 mm. In some embodiments, the light pipe may have an aperture of 4 mm, and the diamond material may have a coupled surface with a height of 0.6 mm and a length of 2 mm, or less. The light pipe may have any appropriate length, such as about 25 mm.

As shown in FIG. 9, the light pipe can be positioned such that the end surface of the light pipe adjacent the diamond material is parallel, or substantially parallel, to the associated surface of the diamond material. This arrangement allows the light pipe to capture an increased amount of the light emitted by the diamond material. The alignment of the surfaces of the light pipe and the diamond material ensures that a maximum amount of the light emitted by the diamond material will intersect the end surface of the light pipe, thereby being captured by the light pipe.

The embodiments of the inventive concepts disclosed herein have been described in detail with particular reference to preferred embodiments thereof, but it will be understood by those skilled in the art that variations and modifications can be effected within the spirit and scope of the inventive concepts.

What is claimed is:

1. A system for magnetic detection, comprising:
a magneto-optical defect center material comprising a plurality of magneto-optical defect centers;
a radio frequency (RF) excitation source configured to provide RF excitation to the magneto-optical defect center material;
an optical detector configured to receive an optical signal emitted by the magneto-optical defect center material;
an optical light source; and
an optical waveguide assembly comprising a light pipe and at least one optical filter coating, wherein the optical waveguide assembly is configured to transmit light emitted from the magneto-optical defect center material to the optical detector.

2. The system of claim 1, wherein the optical filter coating transmits greater than about 99% of light with a wavelength of about 650 nm to about 850 nm.

3. The system of claim 1, wherein the optical filter coating transmits less than 0.1% of light with a wavelength of less than about 600 nm.

4. The system of claim 1, wherein the optical filter coating transmits greater than about 99% of light with a wavelength of about 650 nm to about 850 nm, and transmits less than 0.1% of light with a wavelength of less than about 600 nm.

5. The system of claim 1, wherein the optical filter coating is disposed on an end surface of the optical waveguide adjacent the optical detector.

6. The system of claim 1, wherein a first optical filter coating is disposed on an end surface of the optical waveguide adjacent the optical detector, and a second optical filter coating is disposed on an end surface of the optical waveguide adjacent the NV diamond material.

7. The system of claim 1, wherein the light pipe has an aperture with a size that is smaller than a size of the optical detector.

8. The system of claim 1, wherein the light pipe has an aperture with a size greater than a size of a surface of the magneto-optical defect center material adjacent to the light pipe.

9. The system of claim 1, wherein the light pipe has an aperture with a size that is smaller than a size of the optical detector and greater than a size of a surface of the magneto-optical defect center material adjacent the light pipe.

10. The system of claim 1, wherein the optical waveguide assembly further comprises an optical coupling material disposed between the light pipe and the magneto-optical defect center material, and the optical coupling material is configured to optically couple the light pipe to the magneto-optical defect center material.

11. The system of claim 1, wherein the optical waveguide assembly further comprises an optical coupling material disposed between the light pipe and the optical detector, and the optical coupling material is configured to optically couple the light pipe to the optical detector.

12. The system of claim 1, wherein an end surface of the light pipe adjacent to the magneto-optical defect center material extends in a plane parallel to a surface of the magneto-optical defect center material adjacent to the light pipe.

13. The system of claim 1, further comprising a second optical waveguide assembly and a second optical detector, wherein the optical waveguide assembly is configured to transmit light emitted from the magneto-optical defect center material to the optical detector.

14. A system for magnetic detection, comprising:
a magneto-optical defect center material comprising a plurality of magneto-optical defect centers;
a radio frequency (RF) excitation source configured to provide RF excitation to the magneto-optical defect center material;
an optical detector configured to receive an optical signal emitted by the magneto-optical defect center material;
an optical light source; and
an optical waveguide assembly comprising an optical waveguide, wherein the optical waveguide assembly is configured to transmit light emitted from the magneto-optical defect center material to the optical detector.

15. The system of claim 14, wherein the optical waveguide further comprises at least one optical filter coating.

16. The system of claim 15, wherein the optical filter coating transmits greater than about 99% of light with a wavelength of about 650 nm to about 850 nm.

17. The system of claim 15, wherein the optical filter coating transmits less than 0.1% of light with a wavelength of less than about 600 nm.

18. The system of claim 15, wherein the optical filter coating transmits greater than about 99% of light with a wavelength of about 650 nm to about 850 nm, and transmits less than 0.1% of light with a wavelength of less than about 600 nm.

19. The system of claim 15, wherein the optical filter coating is disposed on an end surface of the optical waveguide adjacent the optical detector.

20. The system of claim 15, wherein a first optical filter coating is disposed on an end surface of the optical waveguide adjacent the optical detector, and a second optical filter coating is disposed on an end surface of the optical waveguide adjacent the magneto-optical defect center material.

21. A method for magnetic detection using a magneto-optical defect center material comprising a plurality of magneto-optical defect centers, the method comprising:
providing radio frequency (RF) excitation to the magneto-optical defect center material by an RF excitation source;
transmitting light emitted from the magneto-optical defect center material to an optical detector using a waveguide assembly comprising a light pipe; and
receiving an optical signal comprising the light emitted by the magneto-optical defect center material by the optical detector.

22. The method of claim 21, wherein the waveguide assembly comprises a light pipe.

23. The method of claim 21, wherein the optical waveguide assembly further comprises at least one optical filter coating.

24. The method of claim 23, wherein the optical filter coating transmits greater than about 99% of light with a wavelength of about 650 nm to about 850 nm.

25. The method of claim 23, wherein the optical filter coating transmits less than 0.1% of light with a wavelength of less than about 600 nm.

26. The method of claim 23, wherein the optical filter coating transmits greater than about 99% of light with a wavelength of about 650 nm to about 850 nm, and transmits less than 0.1% of light with a wavelength of less than about 600 nm.

27. A system for magnetic detection, comprising:
a magneto-optical defect center material comprising a plurality of magneto-optical defect centers;
a means for providing RF excitation to the magneto-optical defect center material;
a means for receiving an optical signal emitted by the magneto-optical defect center material by an optical detector;
an optical light source; and
a means for transmitting light emitted from the magneto-optical defect center material to the optical detector.
